(19) United States
(12) Patent Application Publication
(10) Pub. No.: US 2012/0019913 A1
(43) Pub. Date: Jan. 26, 2012

(54) Lens Manufacturing Method and Lens

(75) Inventors: Keiji NISHIMOTO, Ina-shi (JP); Takashi NOGUCHI, Shiojiri-shi (JP); Hiroyuki SEKI, Matsumoto-shi (JP)

(73) Assignee: SEIKO EPSON CORPORATION, Tokyo (JP)

(21) Appl. No.: 13/187,386

(22) Filed: Jul. 20, 2011

(30) Foreign Application Priority Data
Jul. 26, 2010 (JP) 2010-166795

(51) Int. Cl. G02B 1/11; C23C 16/50; C23C 16/48; G02B 1/12; C23C 16/40

(52) U.S. Cl. 359/581; 359/642; 427/576

(57) ABSTRACT

A lens manufacturing method comprising:forming a first layer directly or via a second layer on an optical base; and forming a light-transmissive thin film on a surface of the first layer in a physical vapor deposition process, the light-transmissive thin film including a portion made of TiOₓ (0<X≦2) containing Ti-CO₃, wherein forming the light-transmissive thin film in the physical vapor deposition process includes ionizing a gas containing at least one substance containing carbon and irradiating TiOₓ (0<X≦2) with the ionized gas.

This application claims priority to Japanese Patent Application No. 2010-166795, filed Jul. 26, 2010, the entirety of which is hereby incorporated by reference.

### BACKGROUND

1. Technical Field

The present invention relates to a lens and a lens manufacturing method.

2. Related Art

In a typical spectacle lens, a base (optical base) that provides a variety of functions is first prepared, and layers (films) having a variety of functions for enhancing and protecting the functions of the base are then formed on a surface of the base. Known examples of the layers (films) having a variety of functions include a hard-coated layer for ensuring durability of the base of the lens and an antireflection coating for preventing ghost images and flickering. A typical antireflection coating is what is called a multilayer antireflection coating (multilayer film) formed by alternately stacking oxide films having different refractive indices on a hard-coated layer coated on a surface of a base.

JP-A-2004-341052 describes that an optical element formed of a low-heat-resistance base having an antistatic capability is provided. In the description, an optical element, such as a spectacle lens, formed of a plastic optical base on which an antireflection coating having a multilayer configuration including a transparent conductive layer, is provided by forming the transparent conductive layer in an ion-assisted vacuum vapor deposition process and further forming the other layers in the antireflection coating, for example, in an electron beam vacuum vapor deposition process. In the description, the conductive layer is made of an inorganic oxide containing any one of indium, tin, zinc, and other elements or two or more of the elements, in particular, desirably ITO (indium tin oxide: mixture of indium oxide and tin oxide).

To provide a film or a layer formed on a surface of a base with conductivity for antistatic, electromagnetic shielding, and other purposes, it is known to insert an indium tin oxide (ITO) layer. An ITO layer excels in transparency and antistatic property but is not resistant to acid, alkali, or other chemicals. Since human sweat is a saline acid, an antireflection coating including an ITO layer could have a durability problem.

Conductivity can alternatively be provided by forming a thin layer made of gold, silver, or any other suitable metal. Layers formed on a surface of a base of a spectacle lens, such as an antireflection coating, a hard-coated layer, and an antifouling layer, are primarily made of a silicon-based compound or oxide in many cases, and the metal layer described above does not disadvantageously have a strong affinity with the silicon-based layers. Further, gold or other similar elements do not typically have satisfactory adherence, resulting in possible film separation. Silver, when oxidized, may have lowered conductivity in some cases.

### SUMMARY

An advantage of some aspects of the invention is to solve at least part of the problems described above and to provide a lens which includes a layer with conductivity and improved resistance.

According to an aspect of the invention is directed to a lens manufacturing method including: forming a first layer directly or via a second layer on an optical base and forming a light-transmissive thin film on a surface of the first layer in a physical vapor deposition process, the light-transmissive thin film including a portion made of TiOₓ (0<X≦2) containing Ti-CO₃. Forming the light-transmissive thin film in the physical vapor deposition process includes ionizing a gas containing at least one substance containing carbon and irradiating TiOₓ (0<X≦2) with the ionized gas.

TiOₓ (0<X≦2) containing Ti-CO₃ is an electrically low resistant material and highly resistant to acid. On the other hand, in the physical vapor deposition process including ionizing the gas containing at least one substance containing carbon, the ionized gas, that is, an ionized carbon compound, can be involved in the physical vapor deposition process using electron beam or ion assistance. Using the physical vapor deposition process described above therefore allows a thin film made of TiOₓ (0<X≦2) containing Ti-CO₃ to be readily formed on the surface of the first layer so that the resistance of the first layer is lowered. A lens having, for example, an antistatic function and/or an electromagnetic shielding function can therefore be more readily manufactured than in related art.

Physical vapor deposition (PVD) generally refers to a vapor deposition process of evaporating a thin film raw material in a solid form and depositing the evaporated material on a substrate by using heat, laser light, an electron beam, or any other suitable physical action. PVD is a concept including vacuum vapor deposition, sputtering, and ion plating and in recent years, even reactive vacuum vapor deposition, reactive sputtering, and reactive ion plating. In the manufacturing method described above, the gas containing carbon dioxide or any other suitable form of carbon is mixed with a gas to be introduced into an ion gun that emits an ion beam, or the gas to be introduced into the ion gun is replaced with the gas, and the resistance of the first layer can be lowered by using the ionized gas.

The thin film containing TiOₓ (0<X≦2) containing Ti-CO₃ can, although it is thin, sufficiently lower the resistance of the surface of the first layer formed on the base. The thin film is therefore suitable to lower the resistance of the surface of the lens while ensuring satisfactory light transmission of the lens. For example, the conductive thin film containing TiOₓ (0<X≦2) containing Ti-CO₃ (light-transmissive thin film) can be inserted into an antireflection coating employed in the lens as appropriate and having an existing layer structure of related art with no change or very little change in the existing layer structure.

Further, TiOₓ (0<X≦2) containing Ti-CO₃ is resistant to acid, alkali, and other chemicals, unlike ITO. Forming TiOₓ (0<X≦2) containing Ti-CO₃ therefore allows the lens to have not only an antistatic function and/or an electromagnetic shielding function but also satisfactory resistance to acid, alkali, and other chemicals. The lens can be used as a variety of articles, such as a lens (element or product) familiar in everyday life and required to be antistatic and durable, for example, a spectacle lens and a camera lens, a display of an information terminal, and a DVD drive.

In the lens manufacturing method described above, forming a light-transmissive thin film may include irradiating a TiO₂ film with the ionized gas.

Accordingly, a conductive layer formed of the light-transmissive thin film containing TiOₓ (0<X≦2) containing Ti-CO₃ is formed in all or part of the TiO₂ film on the surface of the first layer, whereby a lens having lowered surface resistance can be manufactured.

In the lens manufacturing method described above, forming the light-transmissive thin film, the TiOₓ (0<X≦2) is used as a vapor deposition source and the gas is used as an ion assist gas.

According to the method described above, a conductive layer formed of the light-transmissive thin film containing TiOₓ (0<X≦2) containing Ti-CO₃ is formed in a superficial layer (superficial layer portion, superficial layer region) of the first layer or as a superficial layer of the first layer, whereby a lens having lowered surface resistance can be manufactured.

In the lens manufacturing method described above, forming the light-transmissive thin film includes irradiating a target containing Ti with the ionized gas.

According to the method described above, a conductive film formed of the light-transmissive thin film containing TiOₓ (0<X≦2) containing Ti-CO₃ is formed (as a superficial layer) on the surface of the first layer by using an ion beam containing an ionized carbon compound to sputter TiO₂, whereby a lens having lowered surface resistance can be manufactured.

In the lens manufacturing method described above, the gas may be carbon dioxide.

According to the method described above, the gas is readily handled.

In the lens manufacturing method described above, the lens may include an antireflection coating having a multilayer structure including the first layer.

According to the method described above, the resistance (resistivity) of the antireflection coating having a multilayer structure can be lowered.

The lens manufacturing method described above may further include forming an antifouling layer directly or via a thied layer on the light-transmissive thin film.

According to the method described above, water-repellent, oil-repellent performance of the surface of the lens is improved. Further, the lens even provided with the antifouling layer can be antistatic.

According to another aspect of the invention is directed to a lens including an optical base, a first layer formed directly or via a second layer on the optical base, and a light-transmissive thin film formed on a surface of the first layer, the light-transmissive thin film including at least a portion made of TiOₓ (0<X≦2) containing Ti-CO₃.

TiOₓ (0<X≦2) containing Ti-CO₃ is a low resistant material and highly resistant to acid. A lens having, for example, an antistatic function and/or an electromagnetic shielding function can therefore be more readily provided than in related art.

According to another aspect of the invention is directed to a lens including: an optical base, a first layer formed directly or via a second layer on the optical base, and a light-transmissive and conductive thin film formed on a surface of the first layer. The light-transmissive and conductive thin film includes a portion made of a material at least having a peak at 290 eV in a C1s spectrum detected by X-ray photoelectron spectroscopy (XPS).

According to the lens described above, the resistance of the first layer can be lowered. A lens having, for example, an antistatic function and/or an electromagnetic shielding function can therefore be more readily provided than in related art.

In the lens described above, the light-transmissive thin film may further includes a portion made of TiOₓ.

According to the lens described above, the resistance of the first layer can be further lowered.

The lens described above may further include an antireflection coating having a multilayer structure including the first layer.

According to the lens described above, the resistance (resistivity) of the antireflection coating having a multilayer structure can be lowered.

The lens described above may further include an antifouling layer formed directly or via a third layer on the antireflection coating.

According to the lens described above, water-repellent, oil-repellent performance of the surface of the lens is improved. Further, the lens even provided with the antifouling layer can be antistatic.

In the lens described above, the optical base may be a plastic lens base.

According to the lens described above, the optical base is not damaged by heat or arc and hence has stable quality.

Another aspect of the invention is directed to spectacles including spectacle lenses each of which is any of the lenses described above and a frame to which the spectacle lenses are attached. Since the electrostatic property of a surface of each of the spectacle lenses can be so controlled that the amount of electrostatic charge is reduced, dirt, dust, and other foreign matter unlikely adhere to the surface of the spectacle lens. The surface of the spectacle lens can be further provided with electromagnetic shielding performance. Moreover, the surface of the spectacle lens is resistant to sweat and chemicals and hence has satisfactory durability.

Still another aspect of the invention is directed to a system including any of the lenses described above and a window with one side of each of which faces outward and allowing a user to view an image through the lens and the window. Typical examples of the system include a watch, a display apparatus, a terminal including a display apparatus, and other information processing apparatus. The electrostatic property of a surface of a display apparatus can be so controlled that the amount of electrostatic charge is reduced, and electromagnetic shielding performance thereof can be improved.

Yet another aspect of the invention is directed to a system including any of the lenses described above, a window, and an image forming apparatus that projects an image through the lens and the window. A typical example of the system is a projector, and typical examples of the lens and the window are a lens, a dichroic prism, and a cover glass plate through which an image is projected. The lens described above may be used in an LCD (liquid crystal device) or any other light valve, which is one type of the image forming apparatus, or in an element accommodated therein.

Still yet another aspect of the invention is directed to a system including any of the lenses described above, a window, and an image capturing apparatus that acquires an image through the lens and the window. A typical example of the system is a camera, and typical examples of the lens and the window are a lens and a cover glass plate through which an image is captured. The lens described above may be used with a CCD, which is one type of the image capturing device.

Further another aspect of the invention is directed to a system including any of the lenses described above and a medium accessed through the lens. Typical examples of the system are a DVD drive or other information recording apparatus having a recording medium built therein and desirably having an electrostatic property that allows the amount of electrostatic charge on a surface of the DVD drive to be reduced, and a decorative article having a medium having an aesthetic appearance built therein, and other apparatus.

### BRIEF DESCRIPTION OF THE DRAWINGS

The invention will be described with reference to the accompanying drawings, wherein like numbers refer to like elements.

FIG. 1 is a cross-sectional view showing the structure of a typical lens according to an embodiment of the invention.

FIG. 2 shows the configuration of a sample for XPS according to the embodiment.

FIG. 3 is a table showing conditions under which the XPS sample according to the embodiment is produced.

FIG. 4 is a graph showing components of carbon dioxide gas plasma according to the embodiment.

FIG. 5 is a graph showing a C1s spectrum obtained in XPS according to the embodiment.

FIG. 6 is a graph showing an O1s spectrum obtained in XPS according to the embodiment.

FIG. 7 is a graph showing a Ti2p spectrum obtained in XPS according to the embodiment.

FIG. 8 is a graph showing waveform separation in the C1s spectrum according to the embodiment.

FIG. 9A shows a photoelectron pickup angle in XPS according to the embodiment, and FIG. 9B is a table showing atomic concentration versus change in the photoelectron pickup angle.

FIG. 10 is a table showing the configuration of an antireflection coating according to the embodiment.

FIG. 11 diagrammatically shows an example of a vapor deposition apparatus used to manufacture the antireflection coating according to the embodiment.

FIGS. 12A to 12C diagrammatically show formation of a layer containing TiOₓ (0<X≦2) containing Ti-CO₃ on the surface of the uppermost (outermost) high refractive index layer, which is taken as a first layer, according to the embodiment.

FIG. 13 shows results of evaluation of Examples according to the embodiment and Comparative Examples.

FIGS. 14A and 14B show how to measure sheet resistance of each sample according to the embodiment.

FIG. 15A shows an external appearance of a testing apparatus used in a scratching step of an anti-chemical test according to the embodiment, and FIG. 15B shows an internal structure of the testing apparatus according to the embodiment.

FIG. 16 Shows that the testing apparatus used in the scratching step of the anti-chemical test according to the embodiment is rotated.

FIG. 17 schematically shows an apparatus used to judge the degree of bulging in an anti-moisture test according to the embodiment.

FIG. 18A diagrammatically shows a state in which no bulging occurs on the surface of a lens according to the embodiment, and FIG. 18B diagrammatically shows a state in which bulging occurs on the surface of a lens according to the embodiment.

FIGS. 19A and 19B diagrammatically show formation of a layer containing TiOₓ (0<X≦2) containing Ti-CO₃ according to the embodiment.

FIGS. 20A and 20B diagrammatically show formation of a layer containing TiOₓ (0<X≦2) containing Ti-CO₃ according to the embodiment, FIG. 20A showing that a titanium target according to the embodiment is irradiated with ionized carbon dioxide gas and argon gas and FIG. 20B showing a layer containing TiOₓ (0<X≦2) containing Ti-CO₃ (light-transmissive thin film) formed on a ZrO₂ layer (sixth layer) according to the embodiment in a sputtering process.

FIG. 21 shows an example of spectacles according to the embodiment.

FIG. 22 schematically shows an example of a projector according to the embodiment.

FIG. 23 schematically shows an example of a digital camera according to the embodiment.

FIG. 24 schematically shows an example of a recording medium according to the embodiment.

### DESCRIPTION OF EXEMPLARY EMBODIMENTS

The following description will be made of a spectacle lens as an example of a lens.

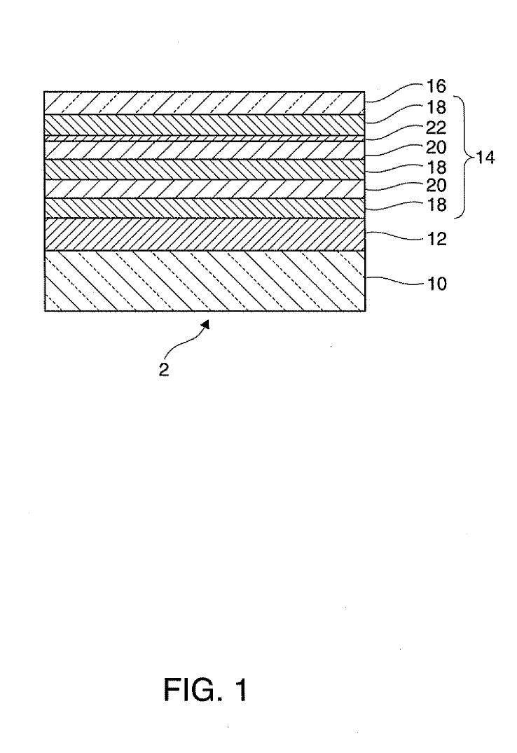

FIG. 1 is a cross-sectional view showing the structure of a typical lens according to an embodiment of the invention. A lens 2 includes an optical base (lens base) 10, a hard-coated layer 12 formed on a surface of the lens base 10, a light-transmissive, antireflection coating 14 formed on the hard-coated layer 12, and an antifouling layer 16 formed on the antireflection coating 14. The antifouling layer 16 can be omitted.

### 1. Summary of Lens

### 1.1 Lens Base

The material of which the lens base 10 is made is not particularly limited to a specific one but can, for example, be a (meth)acrylic resin, which is most frequently used; a styrene resin; a polycarbonate resin; an allyl resin; an allyl carbonate resin, such as a diethylene glycol bis-allylcarbonate resin (CR-39); a vinyl resin; a polyester resin; a polyether resin; a urethane resin obtained in a reaction between an isocyanate compound and a hydroxy compound, such as diethylene glycol; a thiourethane resin obtained in a reaction between an isocyanate compound and a polythiol compound; and a transparent resin obtained by hardening a polymerized composition containing a (thio)epoxy compound having one or more disulfide bonds in a molecule. The refractive index of the lens base 10 ranges, for example, from approximately 1.64 to 1.75. The refractive index of the lens base 10 does not necessarily fall within the range described above and may be a value greater or smaller than those in the range described above.

### 1.2 Hard-coated Layer (Primer Layer)

The hard-coated layer 12 improves (provides) an anti-scratch property. The hard-coated layer 12 can, for example, be made of an acrylic-based resin, a melamine-based resin, a urethane-based resin, an epoxy-based resin, a polyvinyl acetal-based resin, an amino-based resin, a polyester-based resin, a polyamide-based resin, a vinyl alcohol-based resin, a styrene-based resin, a silicon-based resin, or a mixture thereof or a copolymer thereof.

The hard-coated layer 12 is, for example, made of a silicon-based resin. The hard-coated layer 12 made of a silicon-based resin can, for example, be formed by preparing a coating composition containing a silicon-based resin or any other suitable resin component, metal oxide particles, and a silane compound, applying the coating composition to the lens base 10, and hardening the coating composition. The coating composition may further contain colloidal silica, a polyfunctional epoxy compound, and other substances.

Specific examples of the metal oxide particles contained in the coating composition for forming the hard-coated layer 12 (hard-coated layer forming coating composition) are particles made of a metal oxide, such as SiO₂, Al₂O₃, SnO₂, Sb₂O₅, Ta₂O₅, CeO₂, La₂O₃, Fe₂O₃, ZnO, WO₃, ZrO₂, In₂O₃, and TiO₂, or complex particles made of an oxide of two or more metals. The particles are, for example, dispersed in a dispersing medium (for example, water, alcohol-based or other organic solvent) to form a colloid, which is then mixed with the coating composition.

To ensure adherence between the lens base 10 and the hard-coated layer 12, a primer layer may be provided between the lens base 10 and the hard-coated layer 12. The primer layer is also effective in improving an anti-shock property, which a high refractive index lens base lacks. The primer layer can, for example, be made of an acrylic-based resin, a melamine-based resin, a urethane-based resin, an epoxy-based resin, a polyvinyl acetal-based resin, an amino-based resin, a polyester-based resin, a polyimide-based resin, a vinyl alcohol-based resin, a styrene-based resin, a silicon-based resin, or a mixture thereof or a copolymer thereof. A urethane-based resin or a polyester-based resin is preferably used as the primer layer for improving adherence.

A typical method for manufacturing the hard-coated layer 12 and the primer layer includes applying the coating composition by using a dipping, spinner, spray, or flow method and then heating and drying the layers at a temperature ranging from 40 to 200° C. for several hours.

### 1.3 Antireflection Coating

The antireflection coating 14 formed on the hard-coated layer 12 is typically made of an inorganic material. The antireflection coating 14 made of an inorganic material is typically formed of a multilayer film and can be formed, for example, by alternately stacking a low refractive index layer 18 having a refractive index ranging from 1.3 to 1.6 and a high refractive index layer 20 having a refractive index ranging from 1.8 to 2.6. The number of layers that form the multiple layer is, for example, five (typically, three low refractive index layers 18 and two high refractive index layers 20) or seven (typically, four low refractive index layers 18 and three high refractive index layers 20). In the following examples, a light-transmissive thin film 22 is added to the antireflection coating 14. The light-transmissive thin film does not affect basic optical properties of the antireflection coating 14. In the following description, the five or seven-layer antireflection coating 14 including the light-transmissive thin film 22 is sometimes described as including six or eight layers as a whole, but the optical configuration of the antireflection coating 14 is formed of five or seven layers.

The inorganic material of each of the layers that form the antireflection coating 14 can, for example, be SiO₂, SiO, ZrO₂, TiO₂, TiO, Ti₂O₃, Ti₂O₅, Al₂O₃, TaO₂, Ta₂O₅, NdO₂, NbO, Nb₂O₃, NbO₂, Nb₂O₅, CeO₂, MgO, Y₂O₃, SnO₂, MgF₂, WO₃, HfO₂, or Y₂O₃. Any one of the inorganic materials or a mixture of two or more thereof is used.

A typical method for forming the antireflection coating 14 is a dry process, that is, physical vapor deposition including vacuum vapor deposition, ion plating, and sputtering. The vacuum vapor deposition may specifically be an ion beam assisted process in which an ion beam is simultaneously applied in a vapor deposition process.

### 1.4 Antifouling Layer

A water-repellant or hydrophilic anti-fogging layer (antifouling layer) 16 is formed on the antireflection coating 14 in many cases. The antifouling layer 16 is formed on the antireflection coating 14 in order to improve water-repellant, oil-repellent performance of the surface of the spectacle lens 2 and can typically be a layer made of an organic silicon compound containing fluorine. The organic silicon compound containing fluorine can, for example, preferably be a fluorine-containing silane compound.

A fluorine-containing silane compound is preferably used in the form of water-repellent treatment liquid (coating composition for forming antifouling layer) produced by dissolving the fluorine-containing silane compound in an organic solvent and adjusting the concentration thereof to a predetermined value. The antifouling layer 16 can be formed by applying the water-repellent treatment liquid to the antireflection coating 14. An application method can, for example, be dipping or spin coating. The antifouling layer 16 can alternatively be formed by using vacuum vapor deposition or any other dry process along with a metal pellet filled with the water-repellent treatment liquid.

The thickness of the antifouling layer 16 is not particularly limited to a specific value but preferably ranges from 0.001 to 0.5 μm, more preferably from 0.001 to 0.03 μm. When the antifouling layer 16 is too thin, the water-repellent, oil-repellent effect decreases, whereas when being too thick, the surface becomes disadvantageously sticky. Further, when the antifouling layer 16 is thicker than 0.03 μm, the anti-reflection effect may decrease in some cases.

The spectacle lens 2 according to the present embodiment can be achieved by forming the light-transmissive thin film 22, which is a conductive layer, in the antireflection coating 14. In particular, the spectacle lens 2 is required to be not only resistant to acid and alkali but also transparent, and an antistatic material that satisfies the requirements and a method (process) for achieving the requirements are required. In the method, TiO₂ is first deposited in the antireflection coating 14 to a thickness ranging from several nanometers to several tens of nanometers, and the surface of the TiO₂ is irradiated with a carbon dioxide gas ion beam. The antireflection coating 14 is thus provided with conductivity. Specifically, carbon dioxide gas (CO₂) is converted into plasma, to which an energy of several hundreds of electron volts is added, and the resultant ion beam is applied for approximately 60 seconds.

In the present embodiment, when the ionized carbon dioxide gas (including CO, O, CO₂, and C) is applied, the following chemical reactions occur in a superficial region made of Ti0₂.

TiO₂+CO⁺→Ti-CO₃ (1)

TiO₂+CO⁺TiOₓ (0<x<2)+CO₂ (2)

In the chemical reactions, it is speculated that TiO (TiOₓ) and Ti-CO₃ are mixed in the surface of the TiO₂ film.

It is noted that the TiOₓ has a composition in which part of the oxygen atoms is so separated or disengaged that the stoichiometric ratio between the metal atom and the oxygen atom deviates from the ratio between the metal atom and the oxygen atom in the intended compound (nonstoichiometric composition). When TiOₓ is present in TiO₂, a large number of oxygen deficiency (defect) and lattice defect are formed.

It is believed that these defects serve as carriers that provide conductivity (lower sheet resistance).

On the other hand, Ti-CO₃ is a metal carbonate. Since presence of Ti-O₃ produces lattice distortion, it is also speculated that a localized level is formed and that oxygen deficient TiOₓ will not be recombined with oxygen. As a result, the conductivity will not decrease at all or decreases little with time.

Since only surface reactions are used in the present embodiment, only a thin region (several nanometers) undergoes the conductivity treatment, whereby TiO, (0<X≦2) containing Ti-O₃ and TiOₓ, which inherently reduce transparency, can be confined in a thin film. As a result, electric resistance (sheet resistance) can be lowered with very little light absorption, whereby the transparency of the spectacle lens 2 can be ensured. Further, since these materials excel in resistance to acid and alkali, the durability of the spectacle lens 2 is improved.

### 2. Manufacturing Sample for X-ray Photoelectron Spectroscopy (XPS)

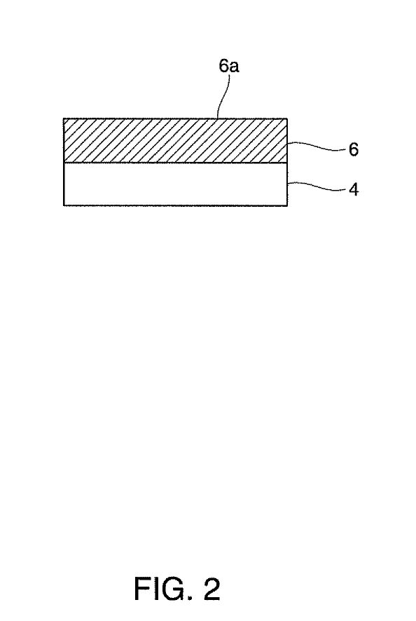

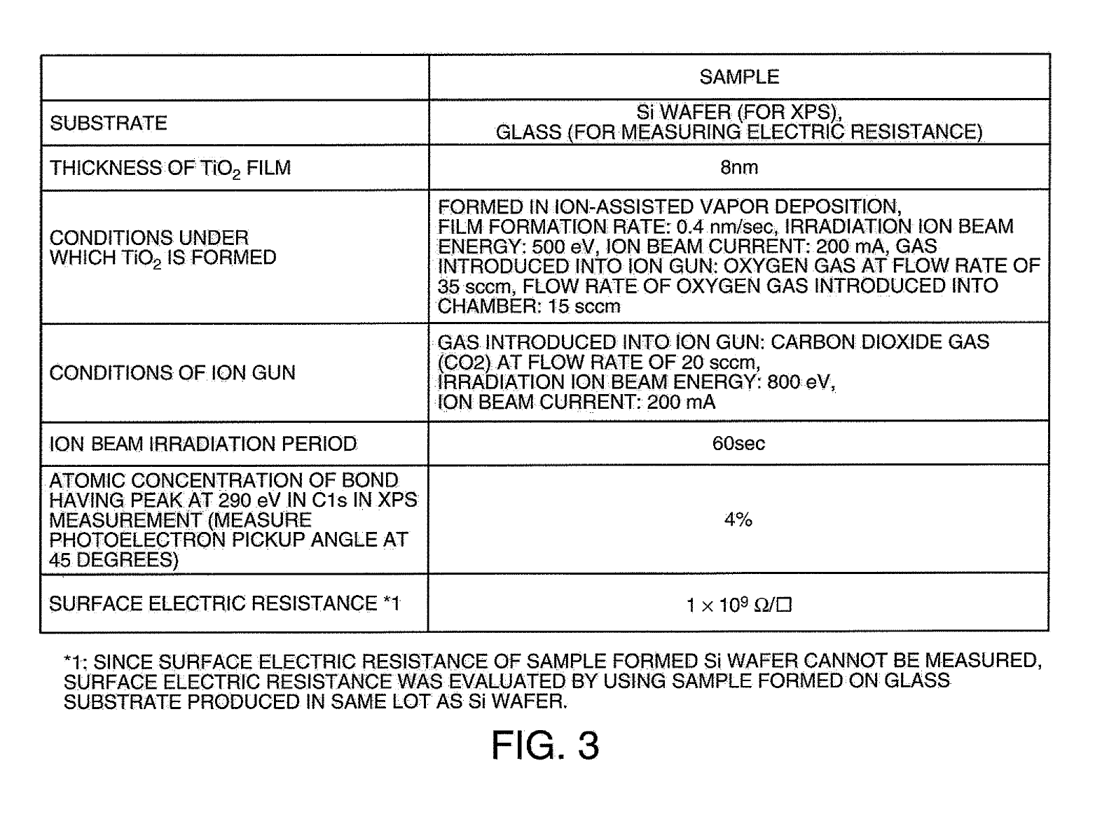

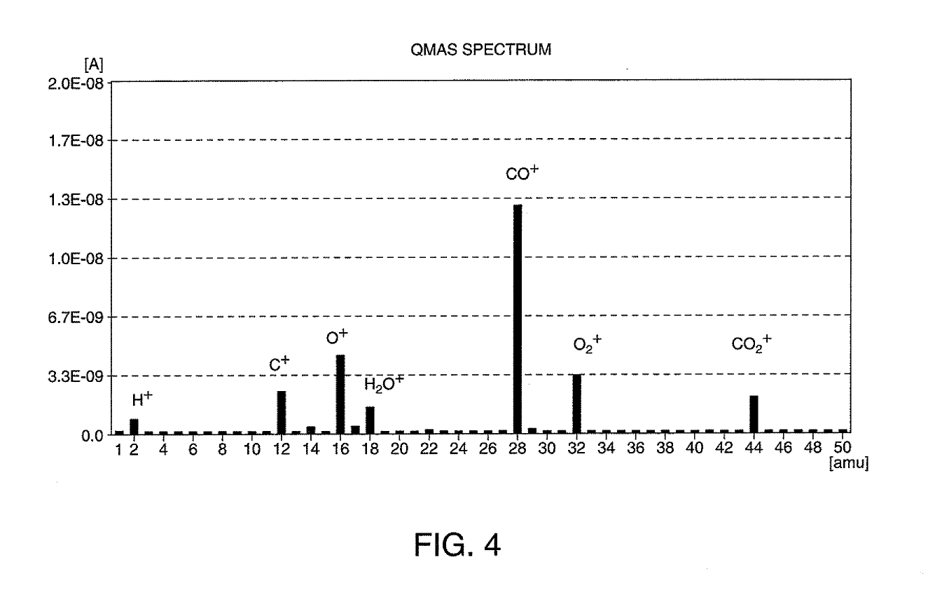

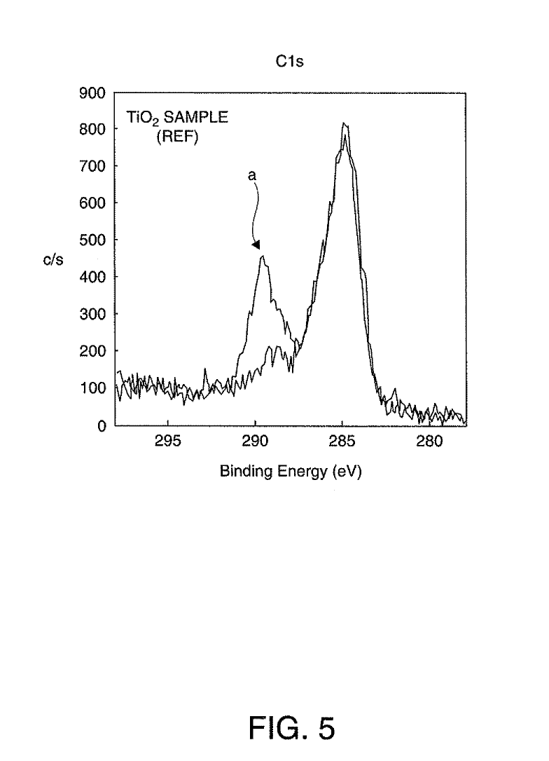

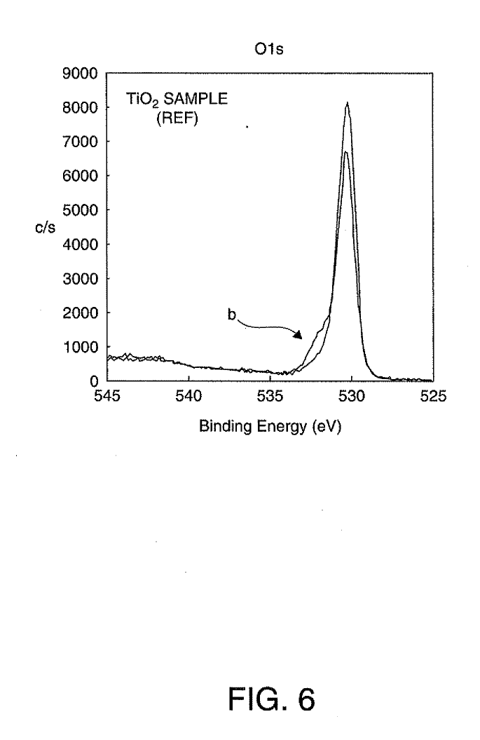

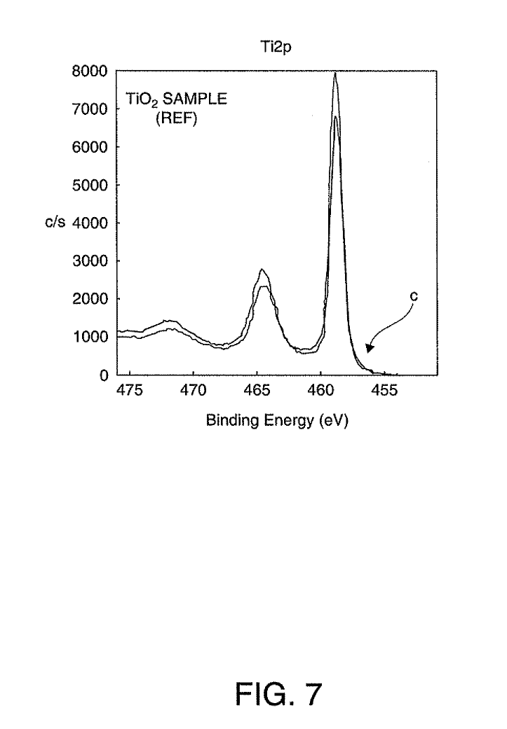

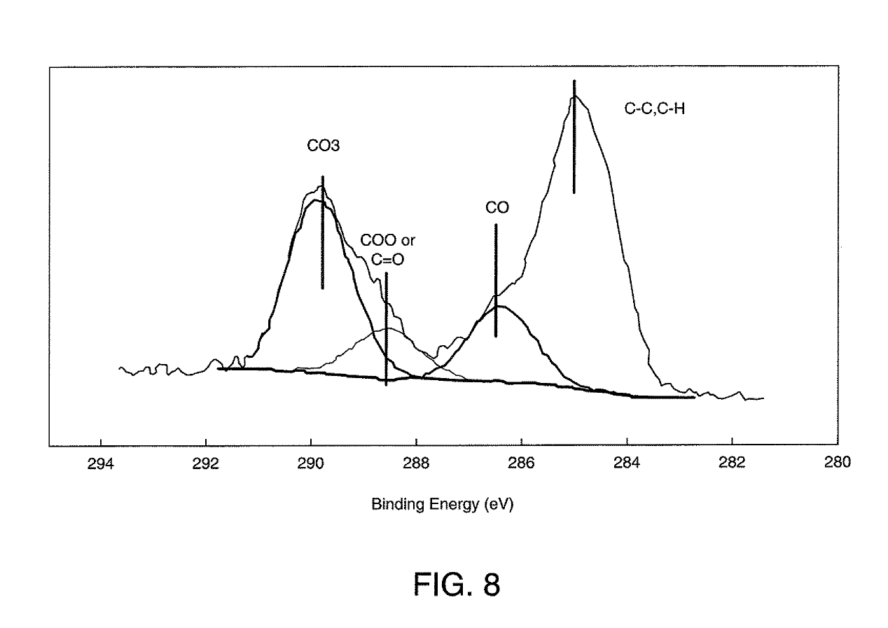

FIG. 2 shows the configuration of a sample for XPS according to the present embodiment. FIG. 3 shows conditions under which the XPS sample according to the present embodiment is produced. FIG. 4 is a graph showing components of carbon dioxide gas plasma according to the present embodiment. FIG. 5 is a graph showing a C1s spectrum obtained in XPS according to the present embodiment. FIG. 6 is a graph showing an O1s spectrum obtained in XPS according to the present embodiment. FIG. 7 is a graph showing a Ti2p spectrum obtained in XPS according to the present embodiment. FIG. 8 is a graph showing waveform separation in the C1s spectrum according to the present embodiment.

An experiment from which Equations (1) and (2) have been derived will first be described. First, a TiO₂ layer 6 was deposited on an Si wafer 4 to a thickness of 8 nm, as shown in FIG. 2. FIG. 3 shows detailed conditions under which the deposition was carried out . An ion beam was then produced from carbon dioxide gas, and a surface 6a was irradiated with the ion beam. FIG. 4 shows the components of the produced carbon dioxide gas plasma measured with a quadrupole mass spectrometer (Q-MAS). A large part of the CO₂ became CO⁺ and O⁺ (instead of CO₂⁺), which formed the irradiation ion beam.

The surface 6a of the TiO₂ layer 6 was irradiated with the ion beam for 60 seconds, and the concentration of each element was analyzed and chemical bond states were studied in XPS. FIG. 5 also shows a spectrum from a sample not having undergone the conductivity treatment (ion beam irradiation) for comparison purposes. A new binding energy peak from the reference sample irradiated with the ion beam was observed in the vicinity of 290 eV (peak resulting from a compound formed by carbon dioxide ion irradiation) in the C1s spectrum (see arrow “a” in FIG. 5). A chemical shift was also observed in the vicinity of 532 eV in the O1s spectrum (see arrow “b” in FIG. 6). It was also ascertained that TiOₓ was present, although by a small amount, in the Ti2p spectrum (see arrow “c” in FIG. 7). The waveform separation in the forms of CO₃, COO, C═O, CO, C—C, and C—H in FIG. 8 shows that CO₃ and COO or C═O were formed by the ion beam irradiation. Equations (1) and (2) described above can be speculated from these results (CO, C—C, and C—H resulted from contamination of the surface of the sample (contamination that occurred between sample production and XPS analysis)).

In the XPS-based measurement method, ULVAC PHI Quantum 2000 was used along with an X-ray source that emits an Al-Kα line (1486.6 eV) . The sample was produced in a vacuum deposition process, temporarily exposed to the atmosphere, and then placed in the XPS apparatus for measurement. Before the XPS measurement, the surface of the sample was not cleaned. The element ratio among O, Ti, and C was calculated from peak areas in the C1s, Ti2P, and O1s spectra obtained by using the Al-Kα line and corrected by sensitivity coefficients. The sensitivity coefficients used in the calculation were 0.711 for O1s, 0.296 for C1s, and 1.798 for Ti2P when the sensitivity coefficient for F1s was 1. Further, deconvolution is performed on the peaks in the C1s spectrum as follows: After background was subtracted from the measured C1s narrow spectrum by using a Shirley method, it was assumed that the following components were present: CO₃ (289.8 eV) , C═O or COO (288.6 eV), CO (286.4 eV), and C—C or C—H (284.8 eV), and a Gaussian-Lorentzian mixed function or a Gaussian function was used along with the combination of the four peaks to perform curve fitting.

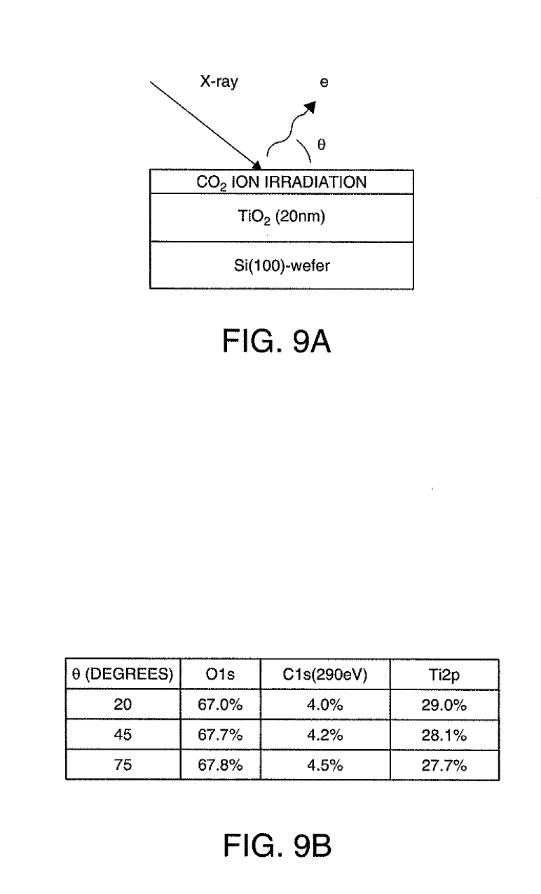

FIG. 9A shows a photoelectron pickup angle in XPS according to the present embodiment, and FIG. 9B is a table showing atomic concentration versus change in the photoelectron pickup angle. As shown in FIG. 9A, the XPS measurement was made by setting the photoelectron pickup angle θ at 20, 45, and 75 degrees, and the curve fitting and quantitative analysis were performed for each of the angles. Since the components CO (286.4 eV) and C—C or C—H (284.8 eV) were also present in the reference sample (TiO₂) as shown in FIG. 5, they were not produced by the surface treatment according to the present embodiment but produced due to surface contamination when the sample was exposed to the atmosphere. The quantification was therefore performed without these components. The results shown in FIG. 9B indicate that the component resulting from CO₃ was approximately 4% (atomicity concentration). Since electric resistance of the surface of the sample on the Si wafer and degradation in the electric resistance cannot be measured, they were evaluated by using a sample formed on a glass substrate produced in the same lot as the Si wafer.

### 3. Sample including SiO₂-ZrO₂-based Antireflection Coating Manufactured in Accordance with First Method

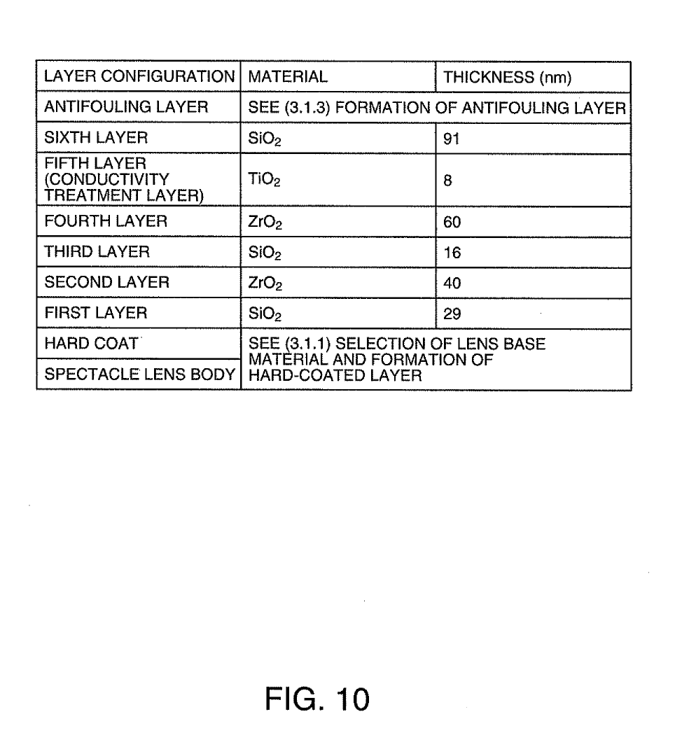

FIG. 10 is a table showing the configuration of the antireflection coating according to the present embodiment. In the spectacle lens 2 according to the present embodiment, the step of manufacturing the sample described above was adapted to the antireflection coating 14 in the spectacle lens 2, as shown in FIG. 10.

A sample including the antireflection coating 14 having SiO₂ layers as the low refractive index layers 18 and ZrO₂ layers as the high refractive index layers 20 was manufactured. Further, the light-transmissive thin film 22 was formed, which will be described later in detail, on the surface of the uppermost (outermost) high refractive index layer 20, which is taken as a first layer, by depositing (forming) TiOₓ (0<X≦2) as a transition metal oxide thin film on the surface of the uppermost (outermost) high refractive index layer 20 and irradiating the TiOₓ (0<X≦2) thin film with an ionized carbon dioxide gas obtained by ionizing carbon dioxide gas.

Samples in the following Examples are called samples S1, S2, and so on, and samples that are not required to be distinguished from one another among Examples are collectively called lens samples 2.

### 3.1 Example 1 (Sample S1)

### 3.1.1 Selection of Lens Base Material and Formation of Hard-coated Layer

The lens base 10 was made of a plastic spectacle lens base material having a refractive index of 1.67 (product name: Seiko Super Sovereign (SSV) (manufactured by SEIKO EPSON CORPORATION)).

An application liquid for forming the hard-coated layer 12 (coating liquid, coating composition) was prepared by mixing 20 weight parts of an epoxy resin-silica hybrid (product name: COMPOCERAN E102 (manufactured by Arakawa Chemical Industries, Ltd.)) with 4.46 weight parts of an acid anhydride-based hardener (product name: hardener liquid (C2) (manufactured by Arakawa Chemical Industries, Ltd.)) and agitating the mixture.

The coating liquid was applied by spin coating to the lens base 10 to a predetermined thickness. The lens base to which the coating liquid was applied was baked at 125° C. for 2 hours so that the hard-coated layer 12 was formed on the lens base 10.

### 3.1.2 Formation of Antireflection Coating

### 3.1.2.1 Vapor Deposition Apparatus

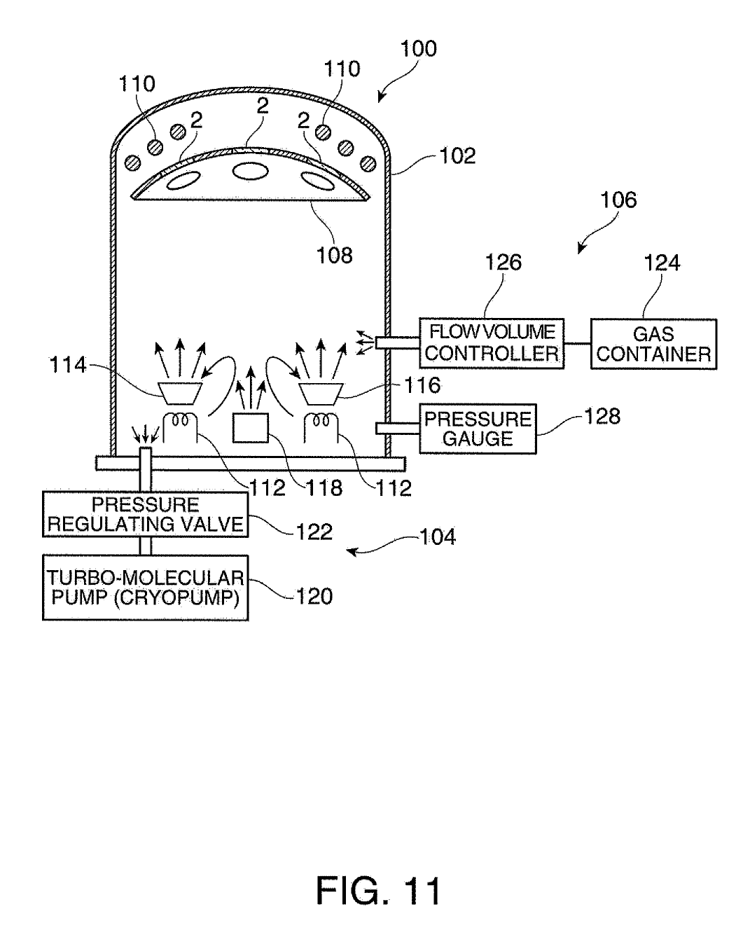

FIG. 11 diagrammatically shows an example of a vapor deposition apparatus used to manufacture the antireflection coating according to the present embodiment. The vapor deposition apparatus 100 shown in FIG. 11 was used to manufacture (form) the antireflection coating 14 made of an inorganic material on the hard-coated layer 12.

The vapor deposition apparatus 100 shown in FIG. 11 is an electron beam vapor deposition apparatus including a vacuum chamber 102, an exhauster 104, and a gas supplier 106. The vacuum chamber 102 includes a sample support mount 108 on which lens samples 2 having the hard-coated layer 12 and the preceding layers formed thereon are placed, base heating heaters 110 for heating the lens samples 2 placed on the sample support mount 108, and filaments 112 that produce hot electrons.

In the vapor deposition apparatus 100, an electron gun (not shown) accelerates the hot electrons, and vapor deposition materials placed in evaporation sources (crucibles) 114 and 116 are irradiated with the hot electrons so that the vapor deposition materials are evaporated and deposited on the lens samples 2.

The vapor deposition apparatus 100 further includes an ion gun 118 that ionizes a gas introduced into the chamber 102 and accelerates and applies the ionized gas to the lens samples 2. The thus configured vapor deposition apparatus 100 can therefore form an ion beam and perform ion assisted vapor deposition.

The vacuum chamber 102 can be further provided with a cold trap for removing residual water, a device for controlling layer thicknesses, and other devices. The device for controlling layer thicknesses is, for example, a reflective optical film thickness meter or a quartz oscillator film thickness meter.

The internal space of the vacuum chamber 102 can be maintained under high vacuum, for example, at 1×10⁻⁴ Pa, by using a turbo-molecular pump or a cryopump 120 and a pressure regulating valve 122 accommodated in the exhauster 104. The internal space of the vacuum chamber 102 can alternatively be maintained under a predetermined gas atmosphere by using the gas supplier 106. The gas supplier 106 includes a gas container 124, a flow volume controller 126, and a pressure gauge 128. The gas container 124 is filled, for example, with the gas (gas made of a substance containing any of carbon, silicon, and germanium (single-element gas or mixed gas)), such as carbon dioxide gas (CO₂); argon gas (Ar); nitrogen gas (N₂); and oxygen gas (O₂). The flow volume of the gas can be controlled by the flow volume controller 126, and the internal pressure in the vacuum chamber 102 can be controlled by the pressure gauge 128.

Each of the base heating heaters 110 is, for example, an infrared lamp and heats the lens samples 2 to degas them or drive water off the samples so that layers formed on the surface of each of, the lens samples 2 reliably adhere thereto.

Primary vapor deposition conditions in the vapor deposition apparatus 100 therefore include the vapor deposition materials, the acceleration voltage and current values of the electron gun, and the presence or absence of ion assistance. When ion assistance is used, the type of ion (atmosphere in vacuum chamber 102) and the voltage and current values of the ion gun 118 are involved. The acceleration voltage of the electron gun is selected from values within the range from 5 to 10 kV and the current value thereof is selected from values within the range from 50 to 500 mA based on a film formation rate and other factors unless otherwise particularly specified. Further, when the ion beam is formed or ion assistance is used, the voltage value of the ion gun 118 is selected from values within the range from 200 V to 1 kV and the current value thereof is selected from values within the range from 100 to 500 mA based on the film formation rate and other factors.

### 3.1.2.2 Formation of Low Refractive Index Layer, High Refractive Index Layer, and Layer Containing TiOₓ (0<X≦2) Containing Ti-CO₃ (Light-transmissive Thin Film)

Each of the lens samples 2 on which the hard-coated layer 12 has been formed was cleaned with acetone and heated in the vacuum chamber 102 at approximately 70° C. so that water attached to the lens sample 2 was evaporated. Ion cleaning was then performed on the surface of the lens sample 2. Specifically, the ion gun 118 was used to irradiate the surface of the lens sample 2 with an oxygen ion beam having an energy of several hundreds of electron volts so that organic substances attached to the surface of the lens sample 2 were removed. The process described above allows a layer (film, first layer 18 described later) to be formed on the surface of the lens sample 2 to adhere thereto firmly. Instead of the oxygen ion, an inert gas, for example, argon (Ar), xenon (Xe), or nitrogen (N₂), maybe used to carry out the process described above. Still alternatively, the surface of the lens sample 2 may be irradiated with oxygen radicals or oxygen plasma.

The internal space of the vacuum chamber 102 was evacuated to a sufficiently high vacuum, and then the low refractive index layer 18 and the high refractive index layer 20 were alternately stacked in an electron beam vacuum vapor deposition process. An inorganic antireflection coating 14 having the following multilayer structure was thus manufactured.

### Low Refractive Index Layer

As first and third layers, each of which is the low refractive index layer 18, SiO₂ layers were formed in a vacuum vapor deposition process without using ion assistance. The film formation rate was set at 2.0 nm/sec. The acceleration voltage of the electron gun for heating the material was set at 7 kV and the current thereof was set at 100 mA.

### High Refractive Index Layer

As second and fourth layers, each of which is the high refractive index layer 20, ZrO₂ layers were formed by heating and evaporating a tablet-shaped ZrO₂ sintered material with the electron beam. The film formation rate was set at 0.8 nm/sec. The acceleration voltage of the electron gun for heating the material was set at 7 kV, and the current thereof was set at 200 mA.

### Layer Containing TiOₓ (0<X≦2) Containing Ti-CO₃ (Light-transmissive Thin Film)

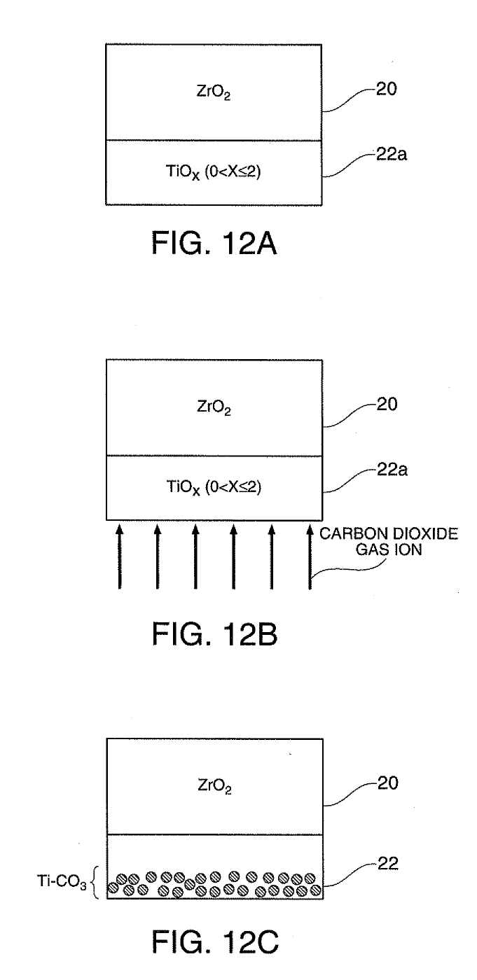

FIGS. 12A to 120 diagrammatically show formation of a layer 22 containing TiOₓ (0<X≦2) containing Ti-CO₃ on the surface of the uppermost (outermost) high refractive index layer 20, which is taken as a first layer, according to the present embodiment. FIGS. 12A to 12C show how the layer 22 containing TiOₓ (0<X≦2) containing Ti-CO₃ (light-transmissive thin film) is formed in the vapor deposition apparatus 100. It is noted that the positional relationship between the high refractive index layer 20 and the light-transmissive thin film 22 in the vertical direction is reversed from that in the lens sample 2 shown in FIG. 1. FIGS. 12A to 12C therefore show the way in which after the first layer 18, the second layer 20, the third layer 18, and the fourth layer 20 are formed on the lens sample 2, the vapor deposition apparatus 100 is used to form a fifth layer (conductive layer), which is a layer containing TiOₓ (0<X≦2) containing Ti-CO₃, specifically, the layer 22 containing TiOₓ (0<X≦2) containing Ti-CO₃ in the present example. That is, in Example 1, the fourth layer 20 is taken as a first layer, and the layer 22 containing TiOₓ (0<X≦2) containing Ti-CO₃ (fifth layer) is the light-transmissive thin film (conductive layer). In the following sections, the layer containing TiOₓ (0<X≦2) containing Ti-CO₃ is simply described as a Ti-CO₃-containing TiOₓ (0<X≦2) layer.

The Ti-CO₃-containing TiOₓ (0<X≦2) layer 22 was formed as follows: First, a TiOₓ (0<X≦2) material was heated with the electron beam and evaporated in anion assisted vapor deposition process. The vapor deposition conditions used in the process described above are shown in FIG. 3. A TiOₓ (0<X≦2) layer 22a was thus formed on the fourth layer 20 to a thickness of 8 nm.

Thereafter, carbon dioxide gas was introduced into the ion gun at 20 sccm and converted into plasma, and the ion energy and the ion current were set at 800 eV and 200 mA, respectively. Under these conditions, a carbon dioxide gas ion beam containing CO₂⁺, CO⁺, C⁺, and other ions was produced from the carbon dioxide gas, with which the TiOₓ (0<X≦2) layer 22a having been formed was irradiated, as shown in FIG. 12B. The period during which the carbon dioxide gas ion beam was applied was set at 120 seconds.

The carbon dioxide gas ion beam is an ion beam produced from carbon dioxide as a raw material and may contain a carbon monoxide ion, a carbon ion, an oxygen ion, which are decomposition products, as well as a carbon dioxide ion. Further, the carbon dioxide gas ion beam may contain not only a univalent ion but also a divalent ion, a trivalent ion, and polyvalent ions. When the TiOₓ (0<X≦2) layer 22a is irradiated with the carbon dioxide gas ion beam, carbon (C) in the TiOₓ (0<X≦2) layer 22a, which forms the superficial layer of the high refractive index layer 20, undergoes mixing and a chemical reaction in which part of the TiOₓ (0<X≦2) is typically converted into TiOₓ (0<X≦2) containing Ti-CO₃. The layer 22 containing TiOₓ (0<X≦2) containing Ti-CO₃ is thus formed, as shown in FIG. 12C.

TiOₓ (0<X≦2) containing Ti-CO₃ is formed in all or part of the TiOₓ layer 22a (typically in the surface thereof) and forms the light-transmissive thin film 22, which serves as a conductive layer. All carbon (C) introduced into the TiOₓ (0<X≦2) layer 22a does not always contribute to the formation of TiOₓ (0<X≦2) containing Ti-CO₃, but holes or electrons having been produced may increase the number of charge carriers and contribute to increase in the conductivity of the light-transmissive thin film 22.

To what level (thickness, depth) in the TiOₓ (0<X≦2) layer 22a carbon (C) is introduced (typically, to what level TiOₓ (0<X≦2) containing Ti-CO₃ is formed) depends on the carbon dioxide gas ion beam irradiation period, the ion energy (voltage), and the ion current. It is believed under the conditions in Example 1 that TiOₓ (0<X≦2) containing Ti-CO₃ or the conductive, light-transmissive thin film 22 is formed in most of the TiOₓ (0<X≦2) layer 22a having a thickness of 8 nm. The TiOₓ (0<X≦2) layer 22a formed on the surface of the fourth layer (ZrO₂ layer) 20 optically functions as a high refractive index layer along with the fourth layer (ZrO₂ layer) 20. As described above, the method for manufacturing the sample S1 is a manufacturing method including irradiating the surface of the TiOₓ (0<X≦2) layer 22a, which is formed on the uppermost or outermost high refractive index layer 20, with the carbon dioxide gas ion beam to lower the resistance of the surface (superficial layer) 22 of the high refractive index layer 20.

### Low Refractive Index Layer

An SiO₂ layer (low refractive index layer 18) was formed as a sixth layer on the Ti-CO₃-containing TiOₓ (0<X≦2) layer 22 under the same conditions as those under which the first and third layers were formed. The film formation rate was set at 2.0 nm/sec, and the acceleration voltage and the current of the electron gun were set at 7 kV and 100 mA, respectively.

In the steps described above, the thicknesses of the first to fourth layers and the sixth layer, on which the optical performance of the antireflection coating 14 primarily depends, were controlled to be 29, 40, 16, 60, and 91 nm, respectively. That is, the layer structure includes the first, third, and sixth layers formed of the low refractive index SiO₂ layer 18, the second and fourth layers formed of the high refractive index ZrO₂ layer 20, and the fifth layer formed of the Ti-CO₃-containing TiOₓ (0<X≦2) layer 22 formed on the surface of (or outside) the outermost high refractive index layer 20.

### 3.1.3 Formation of Antifouling Layer

Oxygen plasma treatment was performed on the lens sample 2 having the antireflection coating 14 and the preceding layers formed thereon, and then the antifouling layer 16 was formed by using a vapor deposition source made of a pellet material containing “KY-130” (product name, manufactured by Shin-Etsu Chemical Co., Ltd.) containing a fluorine-containing organic silicon compound having a large molecular weight. More specifically, KY-130 was heated and evaporated at approximately 500° C. in the vacuum chamber 102 so that the antifouling layer 16 was formed on the antireflection coating 14. The vapor deposition period was set at approximately three minutes. Performing the oxygen plasma treatment on the lens sample 2 having the antireflection coating 14 and the preceding layers formed thereon allows a silanol group to be produced on the surface of the final SiO₂ layer (sixth layer) 18. Chemical adherence (chemical bond) between the antireflection coating 14 and the antifouling layer 16 can be enhanced by forming the antifouling layer 16 after the oxygen plasma treatment.

After the vapor deposition, the lens sample 2 was removed from the vapor deposition apparatus 100, turned upside down, and placed in the vapor deposition apparatus 100 again. The steps described in 3.1.2 to 3.1.3 were repeated in the same order to form the antireflection coating 14 (including formation of the Ti-CO₃-containing TiOₓ (0<X≦2) layer 22) and the antifouling layer 16. The lens sample 2 was then removed from the vapor deposition apparatus 100. In this way, the lens sample S1 of Example 1 was so produced that the hard-coated layer 12, the antireflection coating 14 having the Ti-CO₃-containing TiOₓ (0<X≦2) layer 22 formed therein (as fifth layer), and the antifouling layer 16 were formed on both sides of the lens base 10.

### 3.2 Example 2 (sample S2)

A sample was produced by setting the film thickness of TiO₂ at 10 nm with the other conditions being the same as those in Example 1.

### 3.3 Example 3 (sample S3)

A sample was produced by setting the film thickness of TiO₂ at 12 nm with the other conditions being the same as those in Example 1.

### 3.4 Example 4 (sample S4)

A sample was produced by setting the film thickness of TiO₂ at 15 nm with the other conditions being the same as those in Example 1.

### 3.5 Example 5 (sample S5)

A sample was produced by setting the film thickness of TiO₂ at 8 nm and the ion beam irradiation period at 60 seconds with the other conditions being the same as those in Example 1.

### 3.6 Example 6 (sample S6)

A sample was produced by setting the film thickness of TiO₂ at 8 nm and the ion beam irradiation period at 90 seconds with the other conditions being the same as those in Example 1.

### 3.7 Comparative Example 1 (sample R1)

In Comparative Example 1, the same lens base 10 as that in Example 1 was used, and the hard-coated layer 12 was formed under the same conditions as those in (3.1.1). The antireflection coating 14 and the antifouling layer 16 were further formed on the hard-coated layer 14. A sample R1 was thus manufactured.

The low refractive index layers 18 and the high refractive index layers 20 were formed under the same conditions as those in Example 1 (3.1.2.2).

No Ti-CO₃-containing TiOₓ (0<X≦2) layer was formed. First, a TiOₓ (0<X≦2) material was heated with the electron beam and evaporated in an ion assisted vapor deposition process. The vapor deposition conditions used in the process described above are shown in FIG. 3. A TiOₓ (0<X≦2) layer 22a was thus formed on the fourth layer 20 to a thickness of 8 nm.

No conductivity treatment was then performed. The other conditions and the film formation process were the same as those in Example 1 (see 3.1.2.2). After the antireflection coating 14 was formed, the antifouling layer 16 was formed as in Example 1 (see 3.1.3).

### 3.8 Comparative Example 2 (sample R2)

As a sample R2, the same lens base 10 as that in Example 1 was used, and the hard-coated layer 12 was formed under the same conditions as those in (3.1.1). The antireflection coating was further formed on the hard-coated layer 14. A sample R2 was thus manufactured. The low refractive index layers and the high refractive index layers were formed under the same conditions as those in 3.1.2.2 described above.

The fifth layer (conductive layer) was formed by depositing indium tin oxide (ITO) in an ion assisted vacuum vapor deposition process to a thickness of 8 nm. That is, after the fourth layer (ZrO₂ layer) was formed, ITO was deposited in an ion assisted vacuum vapor deposition process to a thickness of 8 nm to form an ITO layer as the fifth layer (conductive layer). To form the ITO film, an ITO sintered material was used as a raw material, and the acceleration voltage and the current value of the electron gun were set at 7 kV and 50 mA, respectively. Further, to encourage oxidization of the ITO film, oxygen gas was introduced at 15 sccm into the vacuum chamber to form an oxygen atmosphere. Further, oxygen gas was introduced at 35 sccm into the ion gun and converted into plasma, and the ion energy and the ion current value were set at 500 eV and 250 mA, respectively. The sample was irradiated with the oxygen ion beam. An SiO₂ layer was then formed as the sixth layer on the ITO layer. The antireflection coating 14 therefore had a six-layer structure including the ITO layer.

After the antireflection coating was formed, the antifouling layer was formed as in Example 1 (see 3.1.3). The sample R2 manufactured in Comparative Example 2 therefore includes the plastic lens base, the hard-coated layer, the antireflection coating including the ITO layer as the fifth layer (conductive layer), and the antifouling layer.

### 3.9 Evaluation of Samples

Each of the low refractive index layers made of silicon dioxide (SiO₂) has a refractive index n of 1.462 at a wavelength of 550 nm. Each of the high refractive index layers made of zirconium dioxide (ZrO₂) has a refractive index n of 2.05 at the wavelength of 550 nm. The TiOₓ (0<X≦2) layer has a refractive index n ranging from 2.3 to 2.4 at the wavelength of 550 nm. The ITO layer has a refractive index n of 2.1 at the wavelength of 550 nm.

The thus manufactured samples S1 (Example 1) to S6 (Example 6), the sample R1 (Comparative Example 1), and the sample R2 (Comparative Example 2) underwent measurement of their sheet resistance and absorption loss. Further, resistance to chemicals (whether or not separation occurs) and resistance to moisture (whether or not bulging occurs) were tested and evaluated for each of the samples.

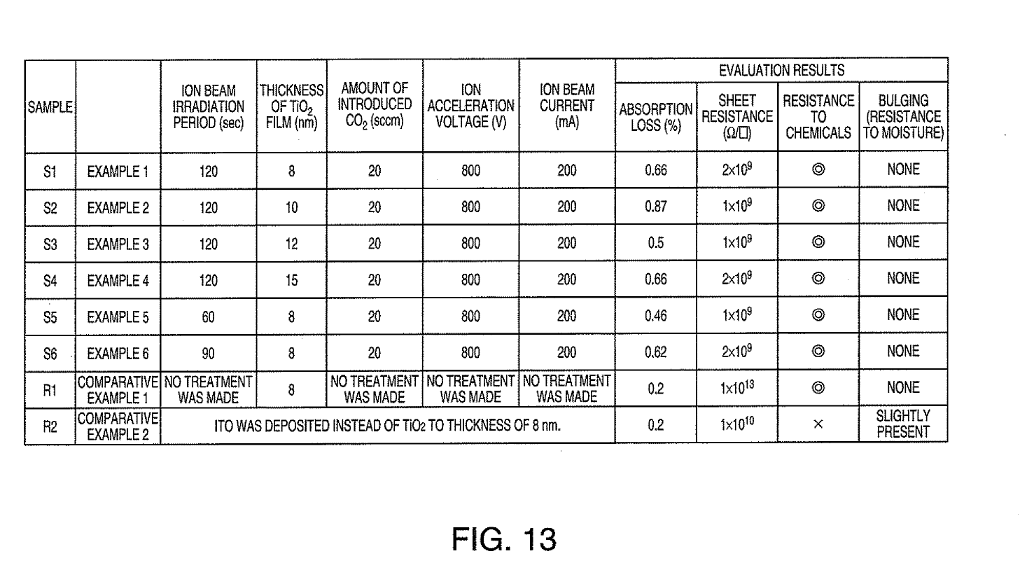

FIG. 13 shows results of evaluation of Examples according to the present embodiment and Comparative Examples.

Descriptions will first be made of the measurement method, the testing method, and the evaluation method.

### 3.10.1 Measurement Method, Testing Method, and Evaluation Method

### 3.10.1.1 Sheet Resistance

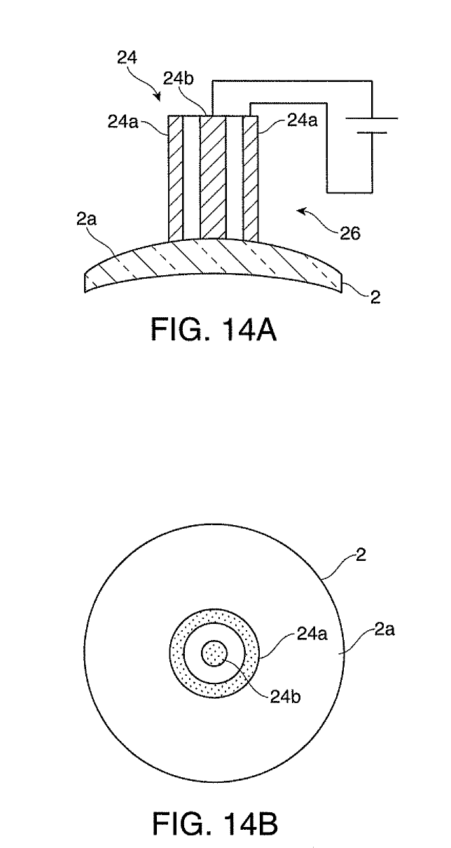

FIGS. 14A and 14B show how to measure sheet resistance of each of the samples according to the present embodiment. In the example shown in FIGS. 14A and 14B, a ring probe 24 was so set as to come into contact with an object to be measured, for example, a surface 2a of a lens sample 2, and the sheet resistance of the surface 2a of the lens sample 2 was measured. A measuring apparatus 26 used in the measurement was a high resistivity measurement meter, Hiresta UP Model MCP-HT450 manufactured by Mitsubishi Chemical Corporation. The ring probe 24 used in the measurement was Type URS having two electrodes, an outer ring electrode 24a having an outer diameter of 18 mm and an inner diameter of 10 mm and an inner circular electrode 24b having a diameter of 7 mm. The sheet resistance of each of the samples was measured by applying a voltage ranging from 10 to 1 kV applied between the electrodes.

### 3.10.1.2 Absorption Loss

It is difficult to measure optical absorption loss when the surface to be measured is curved. To address the problem, the optical absorption loss was evaluated by using samples formed on flat glass substrates produced in the same lot as the samples S1 to S6 described above.

To measure optical absorption loss, a spectrophotometer U-4100 manufactured by Hitachi, Ltd. was used. The spectrophotometer was used to measure the reflectance and transmittance of each of the samples, and the absorptance was calculated by using Equation (3).

Absorptance (absorption loss)=100% −transmittance −reflectance (3)

In the following description, the absorptance is defined as average absorptance averaged across the wavelength range from 400 to 700 nm.

### 3.10.1.3 Resistance to Chemicals

The surface of each of the samples was scratched and then immersed in a chemical solution. Resistance to chemicals was evaluated by observing whether or not the antireflection coating is separated.

### Scratching Step

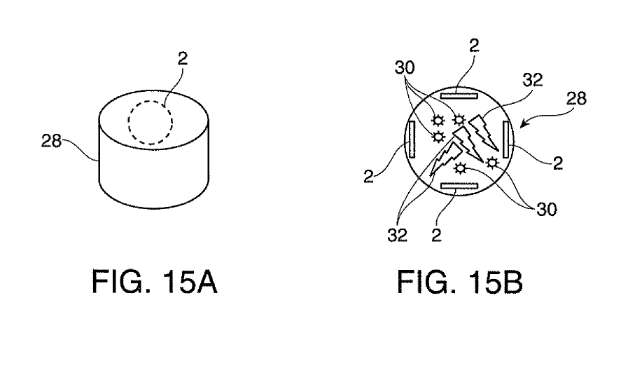

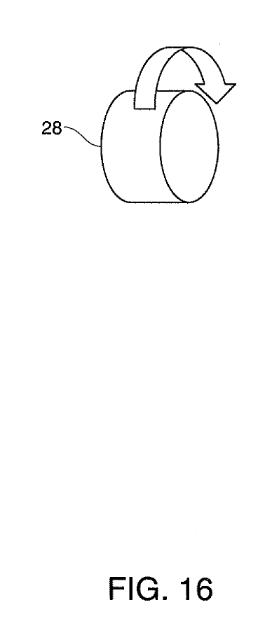

FIG. 15A shows an external appearance of a testing apparatus used in the scratching step of the anti-chemical test according to the present embodiment. FIG. 15B shows an internal structure of the testing apparatus according to the present embodiment. FIG. 16 shows that the testing apparatus used in the scratching step of the anti-chemical test according to the present embodiment is rotated.

Four lens samples 2 under evaluation were attached to an inner wall of a container (drum) 28 shown in FIG. 15A, and nonwoven fabric pieces 30 and sawdust pieces 32 were placed as scratchers in the container (drum) 28, as shown in FIG. 15B. After a lid was placed, the drum 28 was rotated at 30 rpm for 30 minutes, as shown in FIG. 16.

### Chemical Solution Immersing Step

A chemical solution that simulates human sweat (solution obtained by dissolving 50 g of lactic acid and 100 g of salt in 1 L, of pure water) was prepared. The lens samples 2 having undergone the scratching step were immersed in the chemical solution maintained at 50° C. for 100 hours.

### Evaluation Method

Each of the samples having undergone the steps described above was visually evaluated with reference to the sample R2, which was a sample of related art. Judging criteria were as follows.
Grade A: Scratches are hardly visible and transparency is comparable with that of the reference sample
Grade B: Scratches are visible and transparency is poorer than that of the reference sample
Grade C: Layer separation and a large number of scratches are visible and transparency is significantly poorer than that of the reference sample

In the anti-chemical test, all the samples S1 to S6, each of which includes the Ti-CO₃-containing TiOₓ (0<X≦2) layer, showed the Grade-A evaluation result and hence showed excellent resistance to chemicals in the durability test. On the other hand, the sample R2 having the ITO layer formed therein showed the Grade-C evaluation result.

### 3.10.1.4 Bulging (Resistance to Moisture) Steady temperature and moisture environment test

Each of the samples was left in a steady temperature and moisture environment (60° C., 98% RH) for eight days.

### Method for Judging Degree of Bulging (Evaluation Method)

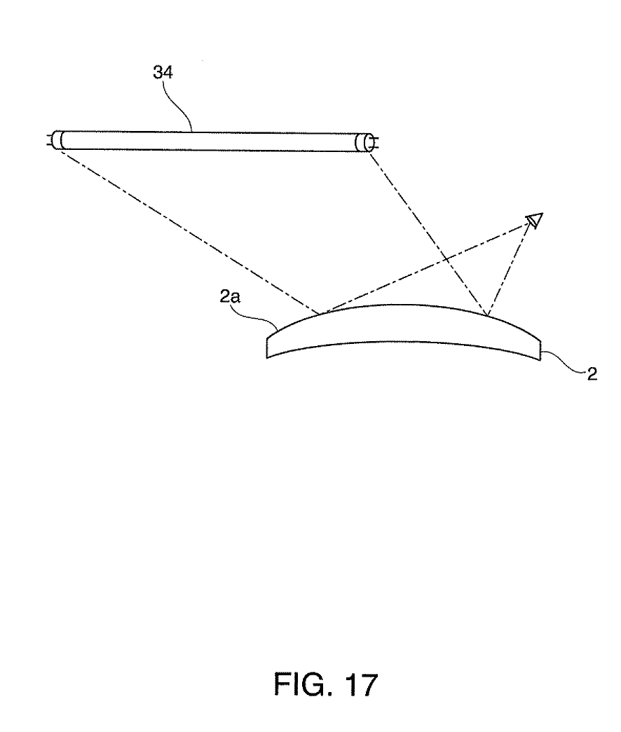

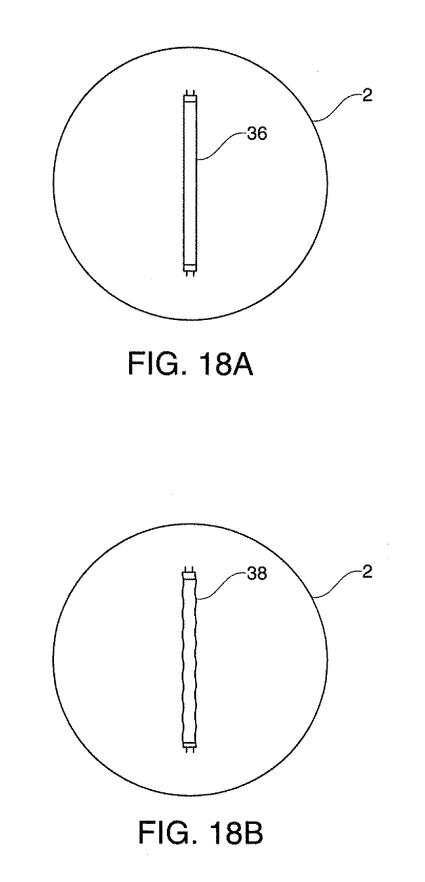

FIG. 17 schematically shows an apparatus used to judge the degree of bulging in an anti-moisture test according to the present embodiment. FIG. 18A diagrammatically shows a state in which no bulging occurs on the surface of a lens according to the present embodiment. FIG. 18B diagrammatically shows a state in which bulging occurs on the surface of a lens according to the present embodiment.

Whether or not bulging has occurred was judged by observing light reflected off the front or rear surface of each of the samples having undergone the steady temperature and moisture environment test described above. Specifically, light originating from a fluorescent lamp 34 and reflected off a convex surface 2a of a lens sample 2 was observed, as shown in FIG. 17. When the contour of an image formed by reflected light 36 from the fluorescent lamp 34 was crisply and clearly observed as shown in FIG. 18A, it was judged that “no bulging occurred.” On the other hand, when the contour of an image formed by reflected light 38 from the fluorescent lamp 34 was observed to be blurred or faint as shown in FIG. 18B, it was judged that “bulging occurred”. As shown in FIG. 13, there was no problem with the electric resistance (sheet resistance) or no bulging occurred in Examples 1 to 6. On the other hand, no bulging occurred but the electric resistance (sheet resistance) was so large that a large amount of dust was attached to the sample in Comparative Example 1, resulting in poor antistatic performance. Comparative Example 2 showed low electric resistance (sheet resistance) and hence excellent antistatic performance but showed slight bulging.

### 3.10.2 Results

### 3.10.2.1 Measured Sheet Resistance

The samples S1 to S6, each of which includes the Ti-CO₃-containing TiOₓ (0<X≦2) layer 22 in the antireflection coating 14, showed measured sheet resistance of 2×10⁹ [Ψ/□], 1×10⁹ [Ω/□], 1×10⁹ [Ω/□], 2×10⁹ [Ω/□], 1×10⁹ [Ω/□], and 2×10⁹ [Ω/□], respectively, as shown in FIG. 13.

In contrast, the sample R1 including no conductive layer (including no Ti-CO₃-containing TiOₓ (0<X≦2) layer 22) showed measured sheet resistance of 1×10¹³ [Ω/□], and the sample R2 including the ITO layer instead of the Ti-CO₃-containing TiOₓ (0<X≦2) layer in the antireflection coating showed measured sheet resistance of 1×10¹⁰ [Ω/□]

As shown from the result of the measurement performed on the sample R1, the sample of related art (glass sample) that had undergone no low resistivity treatment showed a sheet resistance of 1×10¹³ [Ω/□]. In contrast, in the samples S1 to S6, in which the Ti-CO₃-containing TiOₓ(0<X≦2) layer 22 was formed on the surface of one of the layers 20 in the antireflection coating 14, the sheet resistance ranged from 1×10⁹ to 2×10⁹ [Ω/□], which means that the sheet resistance decreases by approximately four orders of magnitude (10⁴) as compared with the sample of related art. That is, the sheet resistance decreases by a factor of 10⁴ and the conductivity is improved accordingly. The samples S1 to S6 therefore have sufficient antistatic performance, as will be described later.

In the sample R2 including the ITO layer in the antireflection coating 14, the sheet resistance was 1×10¹⁰ [Ω/□]. The sheet resistance of each of the samples S1 to S6 in Examples is even smaller than that of the sample R2 of Comparative Example by approximately one order of magnitude (10). That is, the sheet resistance decreases by a factor of 10 and hence the antistatic performance is satisfactory.

As described above, it has been found that providing the Ti-CO₃-containing TiOₓ (0<X≦2) layer 22 allows the electric resistance of the antireflection coating 14 to be greatly lowered, and that incorporating even a thin Ti-CO₃-containing TiOₓ (0<X≦2) layer 22, for example, having a thickness of 8 nm or smaller is still effective in improving conductivity of the surface of the optical base including the antireflection coating 14.

Lowering the sheet resistance of an optical article provides several advantageous effects. Typical advantageous effects include an antistatic effect and an electromagnetic shielding effect. It is believed that a threshold indicating whether or not a spectacle lens has sufficient antistatic performance is a sheet resistance of 1×10¹³ [Ω/□] or lower. In consideration of safety in use and other factors, the sheet resistance measured by using the measurement method described above is more preferably 1×10¹² [Ω/□] or lower. The samples S1 to S6 have been found to have sheet resistance of approximately 1×10⁹ [Ω/□] measured by using the measurement method described above and hence have excellent antistatic performance.

### 3.10.2.2 Measured Absorption Loss

Optical absorption loss tends to increase slightly when the Ti-CO₃-containing TiOₓ (0<X≦2) layer 22 is formed. The increase is, however, approximately 0.87% at the maximum, which means that the spectacle lens has allowable light transmission. It has therefore been found that forming the Ti-CO₃-containing TiOₓ (0<X≦2) layer 22 still ensures sufficient light transmission and allows an optical article to have excellent antistatic performance.

### 3.10.2.3 Evaluation Results of Resistance to Chemicals

It has been found that all the samples S1 to S6, each of which includes the Ti-CO₃-containing TiOₓ (0<X≦2) layer 22, showed Grade-A resistance to chemicals and hence have excellent anti-chemical performance in everyday-life environments. On the other hand, the sample R2 including the ITO layer showed the Grade-C evaluation result.

### 3.10.2.4 Evaluation Results of Bulging (Resistance to Moisture)

All the samples S1 to S6, each of which includes the Ti-CO₃-containing TiOₓ (0<X≦2) layer 22, showed no bulging and hence showed excellent resistance to moisture. On the other hand, the sample R2 including the ITO layer showed an evaluation result of “slight bulging.”

### 3.11 Considerations

The measurement and evaluation results described above have shown that the samples S1 to S6, in each of which the Ti-CO₃-containing TiOₓ (0<X≦2) layer 22 is formed on the surface of one of the layers in the antireflection coating 14, the outermost high refractive index layer 20 in the present embodiment, provide not only greatly lowered sheet resistance but also little degraded resistance to chemical and moisture. The method for providing a TiO₂ layer in advance, ionizing the gas (carbon dioxide gas), and irradiating the surface of the TiO₂ layer with the ionized gas (first method) therefore allows the Ti-CO₃-containing TiOₓ (0<X≦2) layer 22 to be formed on the antireflection coating 14 and enables an optical article having low surface electric resistance, a satisfactory antistatic and other properties, and good durability to be provided.

It has further been found that although forming the Ti-CO₃-containing TiOₓ (0<X≦2) layer 22 causes the absorption loss to be slightly increased, an optical article having negligible absorption loss can be provided by forming a thin Ti-CO₃-containing TiOₓ (0<X≦2) layer 22 to the extent that conductivity high enough to achieve antistatic, electromagnetic shielding, and other purposes is provided.

As described above, providing the Ti-CO₃-containing TiOₓ (0<X≦2) layer 22 in the antireflection coating 14 enables an optical article having excellent antistatic and electromagnetic shielding performance, satisfactory light transmission, and durability to be provided.

To provide antistatic and/or electromagnetic shielding performance, TiOₓ (0<X≦2) containing Ti-CO₃ may not necessarily be uniformly present in the entire surface of a predetermined layer (TiOₓ layer, for example) but may be partially present therein. The presence of such a Ti-CO₃-containing TiOₓ (0<X≦2) layer 22 can still lower the electric resistance of the antireflection coating 22 and hence improve conductivity. That is, the position where the Ti-CO₃-containing TiOₓ (0<X≦2) layer 22 is provided is not limited to the surface of (or a portion outside) the outermost high refractive index layer 20 but may be provided on the surface of any of the layers in the antireflection coating 14 or between any layers therein. Still alternatively, the Ti-CO₃-containing TiOₓ (0<X≦2) layer may be formed on each of a plurality of the layers in the antireflection coating 14.

The conditions in the present embodiment show that the thickness of the TiO₂ film 22a needs to be 8 nm or greater, in which case, a sample irradiated with the carbon dioxide gas ion beam excels in durability of the antistatic performance. The conditions in the present embodiment also show that the ion beam irradiation period needs to be at least 60 seconds (which is also proved from FIG. 13).

When the antireflection coating 14 includes a conductive film made of TiO₂, the conductive film is provided with conductivity by performing conductivity treatment in which the surface of the TiO₂ film is irradiated with an ion beam produced from carbon dioxide gas as a start material. The portion where the conductivity has been provided is actually a conductive layer (film) formed in the TiO₂ thin film and made of a material having a binding peak at 290 eV in the C1s spectrum obtained in XPS. The resultant conductive film has sufficient transparency, conductivity, and durability required for the spectacle lens 2.

None of Comparative Examples shows satisfactory results in all the evaluation items on transparency and resistance to acid and alkali. On the other hand, Examples to 6 having conductive layers formed under different formation conditions provide satisfactory results in almost all the evaluation items, whereby a spectacle lens having satisfactory antistatic functions is provided.

### 4. Sample including SiO₂-ZrO₂-based Antireflection Coating Manufactured in Accordance with Second Method

A method for forming a light-transmissive thin film on the surface of a high refractive index layer 20, which is taken as a first layer, by using TiOₓ (0<X≦2) as a vapor deposition source and using carbon dioxide gas as an ion assist gas for vapor deposition (second method) was used to manufacture a sample including the antireflection coating 14 having SiO₂ layers as the low refractive index layers 18 and ZrO₂ layers as the high refractive index layers 20.

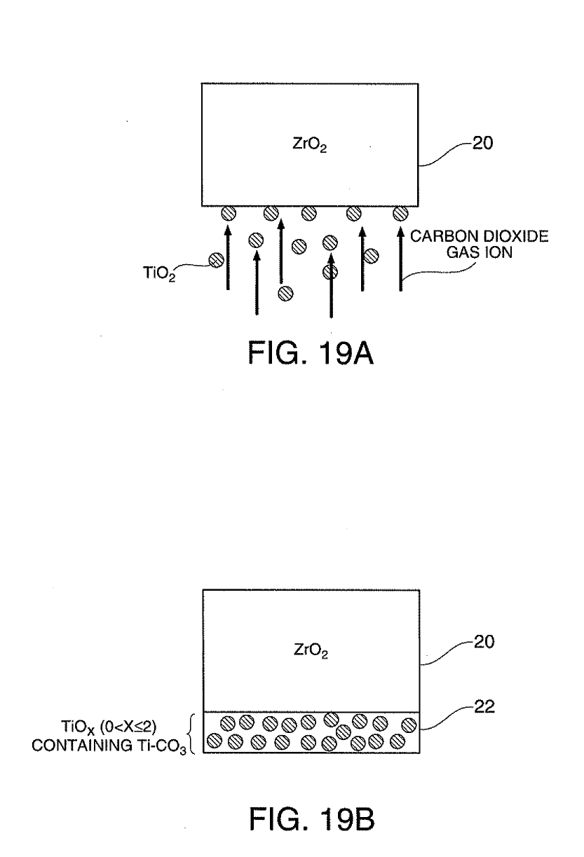

FIGS. 19A and 19B diagrammatically show formation of a layer 22 containing TiOₓ (0<X≦2) containing Ti-CO₃ according to the present embodiment. FIGS. 19A and 19B show formation of a Ti-CO₃-containing TiOₓ (0<X≦2) layer 22 in the vapor deposition apparatus 100. It is noted that the positional relationship between the high refractive index layer 20 and the light-transmissive thin film 22 in the vertical direction is reversed from that in the lens sample 2 shown in FIG. 1. FIGS. 19A and 19B therefore show the way in which after the first layer 18, the second layer 20, the third layer 18, and the fourth layer 20 are formed on a lens sample 2, the vapor deposition apparatus 100 is used to form the Ti-CO₃-containing TiOₓ (0<X≦2) layer 22 as the fifth layer (conductive layer, light-transmissive thin film).

The Ti-CO₃-containing TiOₓ (0<X≦2) layer 22 was formed as follows: As shown in FIG. 19A, TiO₂ used as a vapor deposition source was irradiated with hot electrons and evaporated, and a carbon dioxide gas ion beam was used to apply the evaporated TiO₂ to the fifth layer 22 being formed. The vapor deposition source (used in ion assisted vapor deposition) may alternatively be TiOₓ (0<X≦2). The carbon dioxide gas ion beam was produced by introducing carbon dioxide (CO₂) gas at 20 sccm into the ion gun, converting the carbon dioxide gas into plasma, and setting the ion energy and the ion current at 800 eV and 200 mA, respectively.

Using the carbon dioxide gas ion beam in the ion assisted vapor deposition allows the carbon dioxide gas ion containing CO₂, CO, and C to be deposited along with TiO₂ or TiOₓ, whereby TiOₓ (0<X≦2) containing Ti-CO₃ was deposited as shown in FIG. 19B. In the present embodiment, the Ti-CO₃-containing TiOₓ (0<X≦2) layer was formed to a thickness of 8 nm.

Further, an SiO₂ layer (low refractive index layer 18) was formed as the sixth layer on the Ti-CO₃-containing TiOₓ (0<X≦2) layer 22 under the same conditions as those under which the first and third layers were formed.

In the steps described above, the antireflection coating 14 was so formed that the thicknesses of the first to fourth layers and the sixth layer, on which the optical performance of the antireflection coating 14 primarily depends, were controlled to be 150, 30, 21, 55, and 85 nm, respectively. The thickness of the Ti-CO₃-containing TiOₓ (0<X≦2) layer (fifth layer) 22 forming the superficial layer of the fourth layer 20, which can be so changed that appropriate conductivity is provided, was set, for example, at 8.0 nm.

According to the present embodiment, the method for depositing TiOₓ (0<X≦2), which is a transition metal oxide and used as a vapor deposition source, on one layer 22 in the antireflection coating 14 by using an ionized gas (carbon dioxide gas) as an ion assist gas in ion assisted vapor deposition (second method) allows the conductive Ti-CO₃-containing TiOₓ (0<X≦2) layer 22 to be formed, whereby an optical article having absorption loss substantially comparable with that in related art, being light transmissive (transparent), having satisfactory durability, and having excellent antistatic and electromagnetic shielding performance can be provided.

### 5. Sample including SiO₂-ZrO₂-based Antireflection Coating Manufactured in Accordance with Third Method

A method for forming a light-transmissive thin film in a sputtering process on the surface of a high refractive index layer 20, which is taken as a first layer, by ionizing carbon dioxide gas and irradiating a target made of metal Ti or a titanium oxide with the ionized carbon dioxide gas (third method) was used to manufacture a sample including the antireflection coating 14 having SiO₂ layers as the low refractive index layers 18 and ZrO₂ layers as the high refractive index layers 20.

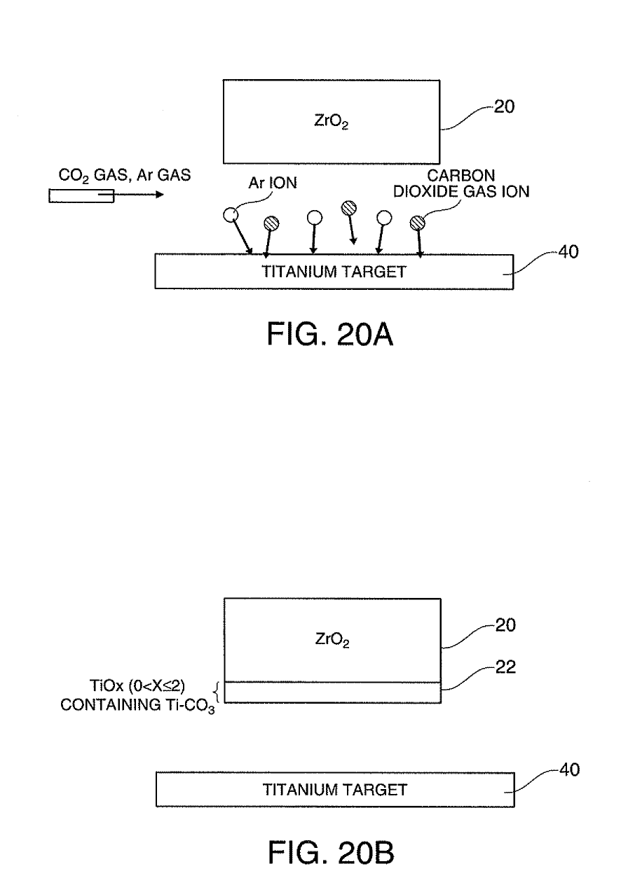

FIGS. 20A and 20B diagrammatically show formation of a layer containing TiOₓ (0<X≦2) containing Ti-CO₃ according to the present embodiment. FIG. 20A shows that the titanium target according to the present embodiment is irradiated with ionized carbon dioxide gas and argon gas. FIG. 20B shows a layer containing TiOₓ (0<X≦2) containing Ti-CO₃ (light-transmissive thin film) formed on a ZrO₂ layer (sixth layer) according to the present embodiment in a sputtering process. In FIGS. 20A and 20B, which show how the layer 22 containing TiOₓ (0<X≦2) containing Ti-CO₃ (light-transmissive thin film) is formed, it is noted that the positional relationship between the high refractive index layer 20 and the light-transmissive thin film 22 in the vertical direction is reversed from that in the lens sample 2 shown in FIG. 1. FIGS. 20A and 20B therefore show the way in which after the first layer 18, the second layer 20, the third layer 18, and the fourth layer 20 are formed on a lens sample 2, the layer containing TiOₓ (0<X≦2) containing Ti-CO₃ is formed.

The Ti-CO₃-containing TiOₓ (0<X≦2) layer 22 was formed as follows: The chamber (vacuum chamber) was evacuated to a sufficiently high vacuum, and a mixture gas of carbon dioxide (CO₂) gas and argon (Ar) gas was introduced into the chamber with the flow volume of the carbon dioxide (CO₂) gas being 100 sccm and the flow volume of the argon (Ar) gas being 200 sccm, and the pressure in the chamber was set at 5.0×10⁻¹ Pa. The carbon dioxide gas and the argon gas were converted into ionized gas by a radio frequency (RF) wave, and a titanium target 40 was irradiated with the ionized gas, as shown in FIG. 20A. The titanium (Ti) element in the titanium target 40 was extracted therefrom in a sputtering process and deposited on the fourth layer 20, as shown in FIG. 20B. In this process, the titanium element reacted with CO, C, and other gases decomposed from CO₂ and was deposited as a Ti-CO₃-containing TiOₓ (0<X≦2) layer 22. The RF power applied to a sputter source was set at 1.5 kW. The Ti-CO₃-containing TiOₓ (0<X≦2) layer 22 was thus formed on the fourth layer 20 to a thickness of 8.0 nm.

An SiO₂ layer (low refractive index layer) 18 was further formed as the sixth layer on the Ti-CO₃-containing TiOₓ (0<X≦2) layer 22 under the same conditions as those under which the first, third, and fifth layers were formed.

According to the present embodiment, the method for producing the Ti-CO₃-containing TiOₓ (0<X≦2) layer in a sputtering process on the surface of one layer 20 in the antireflection coating 14 by using a target containing a transition metal and an ionized gas (carbon dioxide gas) (third method) allows the conductive Ti-CO₃-containing TiOₓ (0<X≦2) layer 22 to be formed, whereby an optical article having absorption loss substantially comparable with that in related art, being light transmissive (transparent), having satisfactory durability, and having excellent antistatic and electromagnetic shielding performance can be provided.

The method for manufacturing an antireflection coating (method for forming Ti-CO₃-containing TiOₓ (0<X≦2) layer 22) including the third method, as well as the manufacturing method including the first or second method, is applicable not only to an SiO₂-ZrO₂-based antireflection coating but also to a SiO₂-TiO₂-based antireflection coating.

The layer containing TiOₓ (0<X≦2) containing Ti-CO₃ (light-transmissive thin film) can also be used, for example, in an antireflection coating formed of three or fewer layers or nine or more layers, and the number of light-transmissive thin films to be formed in the antireflection coating is not limited to one. Further, the combination of the high refractive index layer and the low refractive index layer is not limited to ZrO₂/SiO₂ and TiO₂/SiO₂ but may, for example, be Ta₂O₅/SiO₂, NdO₂/SiO₂, HfO₂/SiO₂, and Al₂O₃/SiO₂, and the light-transmissive thin film described above can be formed on the surface of any of the high and low refractive index layers.

### 6. Examples of System including Optical Article (Spectacle Lens)

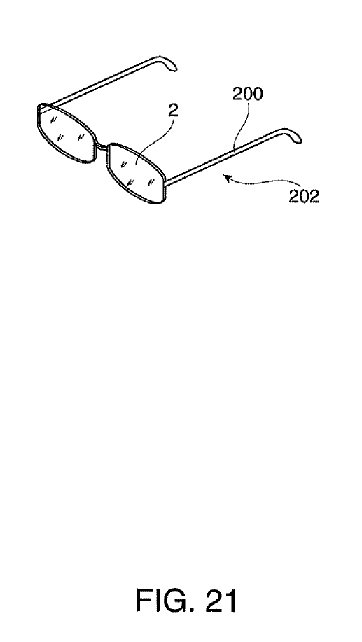

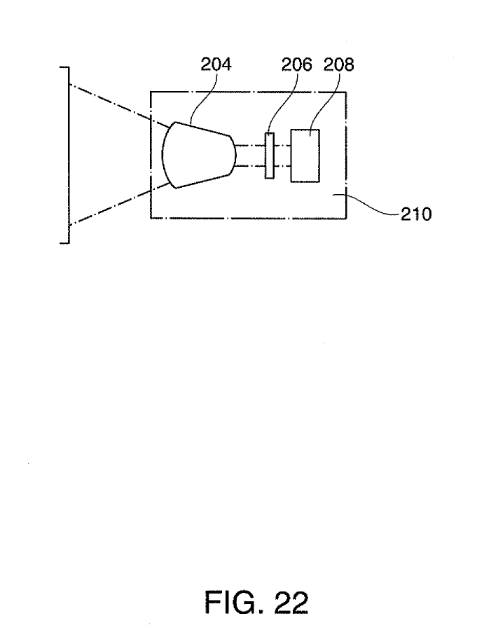

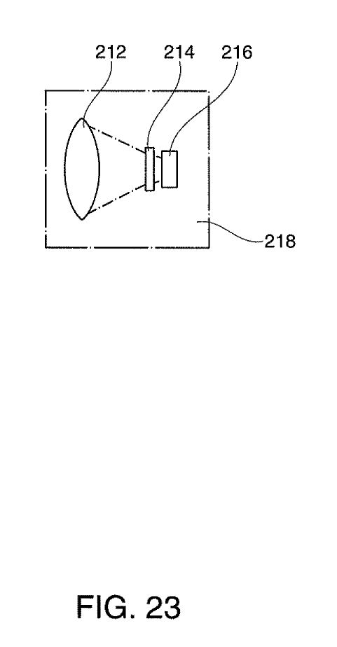

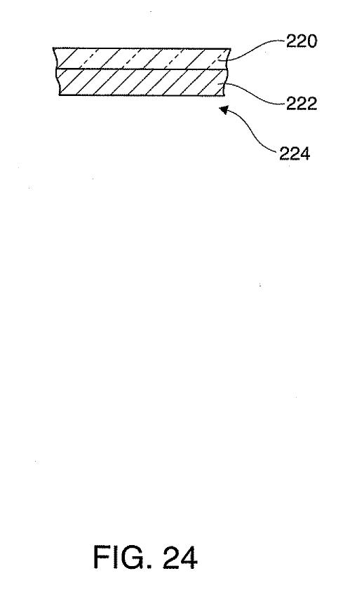

FIG. 21 shows an example of spectacles according to the present embodiment. FIG. 22 schematically shows an example of a projector according to the present embodiment. FIG. 23 schematically shows an example of a digital camera according to the present embodiment. FIG. 24 schematically shows an example of a recording medium according to the present embodiment.

FIG. 21 shows spectacles 202 including spectacle lenses 2, each of which has a Ti-CO₃-containing TiOₓ (0<X≦2) layer according to the present embodiment, and a frame 200 to which the spectacle lenses 2 are attached. FIG. 22 shows an image forming apparatus that includes a lens 204 having a Ti-CO₃-containing TiOₓ (0<X≦2) layer according to the present embodiment and a cover glass plate 206 having the Ti-CO₃-containing TiOₓ(0<X≦2) layer and projects light through the projection lens 204 and the cover glass plate 206. The image forming apparatus shown in FIG. 22 is, for example, a projector 210 including an LCD 208. FIG. 23 shows an image capturing apparatus that includes an image capturing lens 212 having a Ti-CO₃-containing TiOₓ (0<X≦2) layer according to the present embodiment and a cover glass plate 214 having the Ti-CO₃-containing TiOₓ (0<X≦2) layer and acquires an image through the image capturing lens 212 and the cover glass plate 214. The image capturing apparatus shown in FIG. 23 is, for example, a digital camera 218 including a CCD 216. FIG. 24 shows a recording medium, for example, a DVD 224, including a light-transmissive layer 220 formed of a Ti-CO₃-containing TiOₓ (0<X≦2) layer according to the present embodiment and a recording layer 222 on which information can be optically written and read to and from.

A spectacle lens according to the present embodiment can be used in a variety of ways as an optical article in the systems described above, such as a lens, a glass plate, a prism, and a cover layer. The systems described above are presented only by way of example, and any optical articles and systems to which the present embodiment can be applied by those skilled in the art fall within the scope of the present embodiment.

What is claimed is:

1. A lens manufacturing method comprising:
forming a first layer directly or via a second layer on an optical base; and
forming a light-transmissive thin film on a surface of the first layer in a physical vapor deposition process, the light-transmissive thin film including a portion made of TiOₓ (0<X≦2) containing Ti-CO₃,
wherein forming the light-transmissive thin film in the physical vapor deposition process includes ionizing a gas containing at least one substance containing carbon and irradiating TiOₓ (0<X≦2) with the ionized gas.

2. The lens manufacturing method according to claim 1,
wherein forming a light-transmissive thin film includes irradiating a TiO₂ film with the ionized gas.

3. The lens manufacturing method according to claim 1,
wherein forming the light-transmissive thin film, the TiOₓ (0<X≦2) is used as a vapor deposition source and the gas is used as an ion assist gas.

4. The lens manufacturing method according to claim 1,
wherein forming the light-transmissive thin film includes irradiating a target containing Ti with the ionized gas.

5. The lens manufacturing method according to claim 1,
wherein the gas is carbon dioxide.

6. The lens manufacturing method according to claim 1,
wherein the lens includes an antireflection coating having a multilayer structure including the first layer.

7. The lens manufacturing method according to claim 1,
further comprising forming an antifouling layer directly or via a third layer on the light-transmissive thin film.

8. A lens comprising:
an optical base;
a first layer formed directly or via a second layer on the optical base; and
a light-transmissive thin film formed on a surface of the first layer, the light-transmissive thin film including a portion made of TiOₓ (0<X≦2) containing Ti-CO₃.

9. A lens comprising:
an optical base;
a first layer formed directly or via a second layer on the optical base; and
a light-transmissive and conductive thin film formed on a surface of the first layer,
wherein the light-transmissive and conductive thin film includes a portion made of a material at least having a peak at 290 eV in a C1s spectrum detected by X-ray photoelectron spectroscopy (XPS).

10. The lens according to claim 8,
wherein the light-transmissive thin film further includes a portion made of TiOₓ.

11. The lens according to claim 8,
further comprising an antireflection coating having a multilayer structure including the first layer.

12. The lens according to claim 11,
further comprising an antifouling layer formed directly or via a third layer on the antireflection coating.

13. The lens according to claim 8,
wherein the optical base is a plastic lens base.
